(19) United States
(12) Patent Application Publication
(10) Pub. No.: US 2018/0366300 A1
(43) Pub. Date: Dec. 20, 2018

(54) PLASMA POWER TOOL MATCHING USING DC VOLTAGE FEEDBACK

(71) Applicant: Applied Materials, Inc., Santa Clara, CA (US)

(72) Inventors: Soonwook Jung, San Jose, CA (US); Soonam Park, Sunnyvale, CA (US); Dmitry Lubomirsky, Cupertino, CA (US)

(73) Assignee: Applied Materials, Inc., Santa Clara, CA (US)

(21) Appl. No.: 15/625,418

(22) Filed: Jun. 16, 2017

(51) Int. Cl. H01J 37/32; H01L 21/67; H01L 21/66; C23C 16/503; C23C 16/505

(52) U.S. Cl. CPC H01J 37/3299; H01L 21/67069; H01L 21/67253; H01L 22/26; H01J 2237/327; H01J 37/32935; C23C 16/503; C23C 16/505; H01J 37/32357

(57) ABSTRACT

Methods of matching process performance across tools are described. In embodiments, the methods include measuring the DC component of voltage across a plasma configured to process a semiconductor substrate. The RF plasma power is adjusted in response to the measurement of the DC component in a feedback loop to achieve a desired DC voltage. The DC voltage is correlated herein with process characteristics. Feeding back the DC voltage to adjust the RF plasma power has been found to achieve similar process characteristics (e.g. etch rates) despite artificially-introduced variations in plasma hardware which simulated worst-case manufacturing variations. More intuitive feedback options, such as AC voltage amplitude were found to correlate poorly with plasma process characteristics.

### TECHNICAL FIELD

The present technology relates to semiconductor systems, processes, and equipment. More specifically, the present technology relates to matching plasma processes despite hardware variations.

### BACKGROUND

Integrated circuits are made possible by processes which produce intricately patterned material layers on substrate surfaces. Producing patterned material on a substrate requires controlled methods for removal of exposed material. Chemical etching is used for a variety of purposes including transferring a pattern in photoresist into underlying layers, thinning layers, or thinning lateral dimensions of features already present on the surface. Often it is desirable to have an etch process that etches one material faster than another facilitating, for example, a pattern transfer process. Such an etch process is said to be selective to the first material. As a result of the diversity of materials, circuits, and processes, etch processes have been developed with a selectivity towards a variety of materials.

Etch processes may be referred to as wet or dry based on the phase of the etchants used in the process. Wet processes have difficulty penetrating some constrained trenches and also may sometimes deform patterned features. Dry etches are preferred when suitable chemistries are available and known. Dry etch chemistries incorporating remote plasma excitation and ion filtering have broadened the etch selectivities available to semiconductor manufacturers. The broadening appeal of low intensity plasmas and remote plasmas has created a need to improve matching of plasma effect and etch rate from one tool to another.

### SUMMARY

Methods of matching process performance across tools are described. In embodiments, the methods include measuring the DC component of voltage across a plasma configured to process a semiconductor substrate. The RF plasma power is adjusted in response to the measurement of the DC component in a feedback loop to achieve a desired DC voltage. The DC voltage is correlated herein with process characteristics. Feeding back the DC voltage to adjust the RF plasma power has been found to achieve similar process characteristics (e.g. etch rates) despite artificially variations in plasma hardware introduced to simulate worst-case manufacturing variations. More intuitive feedback options, such as AC voltage amplitude were found to correlate poorly with plasma process characteristics.

Methods described herein include methods of forming a plasma. The methods include flowing a precursor into a plasma region. The plasma region is within a substrate processing chamber. The methods further include turning on an RF power to a first RF power level from an RF power supply disposed outside the substrate processing chamber. The methods further include forming a plasma by applying the RF power from the RF power supply across the plasma region. The methods further include measuring a resulting DC voltage across the plasma region. The methods further include calculating a second RF power level from the resulting DC voltage and a setpoint DC voltage. The methods further include changing the RF power from the first RF power level to the second RF power level.

The resulting DC voltage may be between 10 volts and 80 volts. Measuring the resulting DC voltage may include measuring the resulting DC voltage closer to the plasma region than the RF power supply, a matching circuit and a V/I probe so the measurement may be predominantly indicative of properties of the plasma. The plasma region may be a remote plasma region separated from a substrate processing region housing a semiconductor substrate and the remote plasma region is separated from the substrate processing region by a showerhead. The substrate processing region may be plasma-free during excitation of the plasma in the remote plasma region. An electron temperature within the substrate processing region may be less than 0.5 eV during excitation of the plasma. The precursor may include fluorine. The RF power may be between 1 watt and 1,000 watts throughout the plasma. A pressure in the plasma region may be between 70 mTorr and 50 Torr. The plasma region may be a substrate processing region housing a substrate. An RF frequency of the RF power may be less than 200 kHz, between 10 MHz and 15 MHz or greater than 1 GHz during excitation of the plasma.

Methods described herein include methods of forming a remote plasma. The methods include flowing a precursor into a remote plasma region. The remote plasma region is separated from a substrate processing region by a showerhead and a semiconductor substrate is housed within the substrate processing region. Each of the remote plasma region and the substrate processing region is within a substrate processing chamber. The methods may further include forming a remote plasma by applying an RF power from an RF power supply across the remote plasma region. The methods may further include (1) measuring a DC voltage across the remote plasma region, (2) changing the RF power based on the DC voltage measured, and repeating (1) and (2) during application of the RF power. Measuring the DC voltage may include measuring the DC voltage closer to the remote plasma region than the RF power supply, a matching circuit and a V/I probe so the measurement is predominantly indicative of properties of the remote plasma.

Methods described herein include methods of forming a plasma. The methods include flowing a precursor into a remote plasma region. The remote plasma region is separated from a substrate processing region housing a semiconductor substrate by a showerhead. Each of the remote plasma region and the substrate processing region are within a substrate processing chamber. The methods further include forming a remote plasma by applying an RF power from an RF power supply across the remote plasma region. The methods further include measuring a DC voltage across the remote plasma region, and adjusting the RF power from the RF power supply a plurality of times during forming the remote plasma. An amount of adjustment of the RF power depends on the DC voltage measured. The RF power from the RF power supply may be adjusted at least one hundred times while forming the remote plasma. The remote plasma may be capacitively-coupled.

Such technology may provide numerous benefits over conventional systems and techniques. For example, the measurements described herein may be used to achieve similar etch rates despite natural or unavoidable variation among chamber components across multiple etch chambers. The techniques presented herein require less added hardware and produce more reproducible results compared to conventional techniques. These and other embodiments, along with many of their advantages and features, are described in more detail in conjunction with the below description and attached figures.

### BRIEF DESCRIPTION OF THE DRAWINGS

A further understanding of the nature and advantages of the disclosed technology may be realized by reference to the remaining portions of the specification and the drawings.

FIG. 1 shows a top plan view of an exemplary processing system according to the present technology.

FIG. 2 shows a schematic cross-sectional view of an exemplary processing chamber according to the present technology.

FIG. 3 shows a schematic of an exemplary remote plasma power supply matching circuit according to the present technology.

FIG. 4 shows selected operations in a method of forming a plasma in a substrate processing chamber according to the present technology.

FIG. 5 is a chart showing a correlation between etch rate and DC voltage across a process plasma according to embodiments of the present technology.

FIG. 6 is a chart showing a correlation between etch rate and the plasma power supplied by a power supply according to embodiments of the present technology.

FIG. 7A is a chart showing a correlation between etch amount and DC voltage across a process plasma according to the present technology.

Several of the figures are included as schematics. It is to be understood that the figures are for illustrative purposes, and are not to be considered of scale unless specifically stated to be of scale. Additionally, as schematics, the figures are provided to aid comprehension and may not include all aspects or information compared to realistic representations, and may include additional or exaggerated material for illustrative purposes.

In the appended figures, similar components and/or features may have the same reference label. Further, various components of the same type may be distinguished by following the reference label by a letter that distinguishes among the similar components. If only the first reference label is used in the specification, the description is applicable to any one of the similar components having the same first reference label irrespective of the letter.

### DETAILED DESCRIPTION

Methods of matching process performance across tools are described. In embodiments, the methods include measuring the DC component of voltage across a plasma configured to process a semiconductor substrate. The RF plasma power is adjusted in response to the measurement of the DC component in a feedback loop to achieve a desired DC voltage. The DC voltage is correlated herein with process characteristics. Feeding back the DC voltage to adjust the RF plasma power has been found to achieve similar process characteristics (e.g. etch rates) despite artificially variations in plasma hardware introduced to simulate worst-case manufacturing variations. More intuitive feedback options, such as AC voltage amplitude were found to correlate poorly with plasma process characteristics.

During substrate processing to deposit, etch, or treat a patterned substrate, it may be beneficial to have a plasma in a substrate processing chamber. The plasma may be a bias plasma (a local plasma) local to a substrate processing region in embodiments. The plasma may be a remote plasma in a remote plasma region separated from the substrate processing region by a showerhead according to embodiments. However, applying an RF plasma power from either a bias plasma power supply or a remote plasma power supply does not always form the same magnitude plasma in the region across multiple substrate processing chambers. The plasma intensity inside the region varies depending on physical variations in subcomponents as well as variations in assembly. Benefits of the methods described herein include compensating for such variations during processing to achieve reproducible processing results. Exemplary benefits include preventing or reducing deposition rate variation, deposition film property variation, and etch rate variation. Details of the described methods will be presented following a description of exemplary hardware.

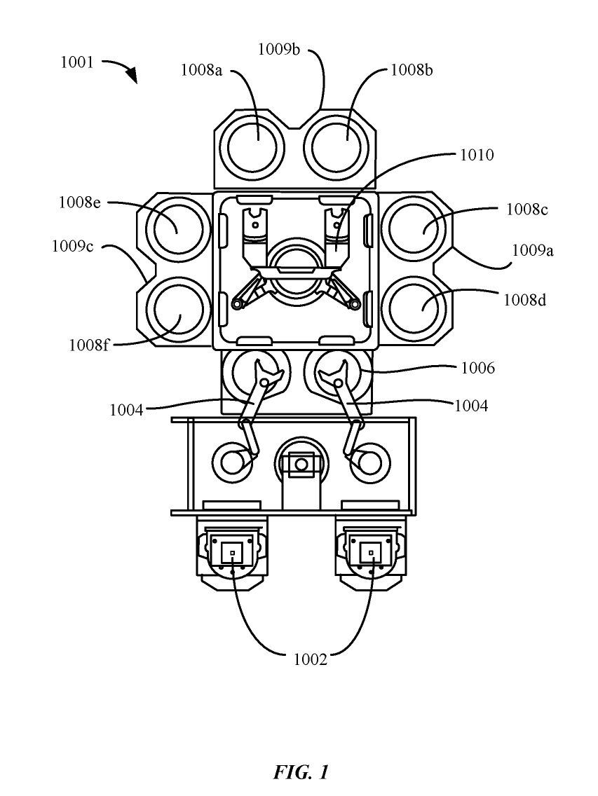

FIG. 1 shows a top plan view of one embodiment of a substrate processing system 1001 of deposition, etching, baking, and curing chambers according to disclosed embodiments. In the figure, a pair of front opening unified pods (FOUPs) 1002 supply substrates of a variety of sizes that are received by robotic arms 1004 and placed into a low pressure holding area 1006 before being placed into one of the substrate processing chambers 1008a-f, positioned in tandem sections 1009a-c. A second robotic arm 1010 may be used to transport the substrate wafers from the holding area 1006 to the substrate processing chambers 1008a-f and back. Each substrate processing chamber 1008a-f, can be outfitted to perform a number of substrate processing operations including the etch processes described herein in addition to cyclical layer deposition (CLD), atomic layer deposition (ALD), chemical vapor deposition (CVD), physical vapor deposition (PVD), epitaxial silicon growth, etch, pre-clean, degas, orientation, and other substrate processes.

The substrate processing chambers 1008a-f may include one or more system components for depositing, annealing, curing and/or etching material films on the substrate wafer. In one configuration, two pairs of the processing chamber, e.g., 1008c-d and 1008e-f, may be used to deposit dielectric material on the substrate, and the third pair of processing chambers, e.g., 1008a-b, may be used to etch the deposited dielectric. In another configuration, all three pairs of chambers, e.g., 1008a-f, may be configured to etch a material on the substrate. Any one or more of the processes described below may be carried out in chamber(s) separated from the fabrication system shown according to embodiments. It will be appreciated that additional configurations of deposition, etching, annealing, and curing chambers for dielectric films are contemplated by system 1001. Many chambers may be utilized in the processing system 1001, and may be included as tandem chambers, which may include two similar chambers sharing precursor, environmental, or control features.

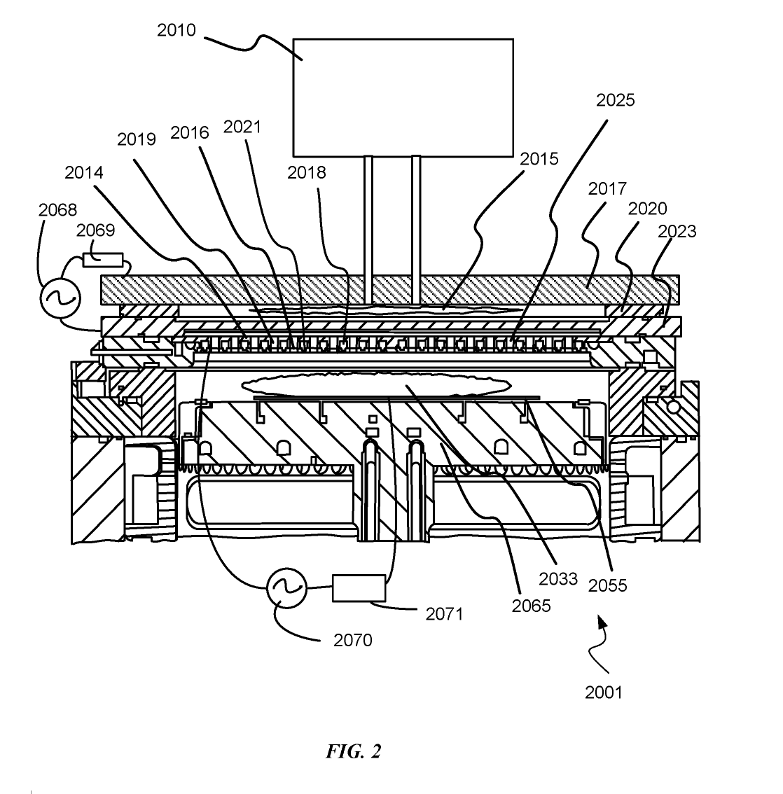

FIG. 2 shows a schematic cross-sectional view of an exemplary substrate processing chamber. The schematic of the substrate processing chamber 2001 serves to introduce the remote and local power supplies but also provide context for alternative configurations and details provided in subsequent descriptions. Later drawings will provide less detail compared to FIG. 2 but only for the sake of brevity. Any combination of features found in FIG. 2 may be present in any or all subsequent embodiments. The substrate processing chamber 2001 has a remote plasma region 2015 and a substrate processing region 2033 inside. The remote plasma region 2015 is partitioned from the substrate processing region 2033 by an ion suppressor 2023 and a showerhead 2025.

A top plate 2017, ion suppressor 2023, showerhead 2025, and a substrate support 2065 (also known as a pedestal), having a substrate 2055 disposed thereon, are shown and may each be included according to any embodiments described herein. The pedestal 2065 may have a heat exchange channel through which a heat exchange fluid flows to control the temperature of the substrate 2055. This configuration may allow the substrate 2055 temperature to be cooled or heated to maintain relatively low temperatures, such as between −20° C. to 200° C. The pedestal 2065 may also be resistively heated to relatively high temperatures, such as between 100° C. and 1100° C., using an embedded heater element.

The etchant precursors flow from the etchant supply system 2010 through the holes in the top plate 2017 into the remote plasma region 2015. The structural features may include the selection of dimensions and cross-sectional geometries of the apertures in the top plate 2017 to deactivate back-streaming plasma in cases where a plasma is generated in remote plasma region 2015. The top plate 2017, or a conductive top portion of the substrate processing chamber 2001, and the showerhead 2025 are shown with an intervening insulating ring 2020, which allows an AC potential to be applied to the top plate 2017 relative to the showerhead 2025 and/or the ion suppressor 2023. The insulating ring 2020 may be positioned between the top plate 2017 and the showerhead 2025 and/or the ion suppressor 2023 enabling a capacitively-coupled plasma (CCP) to be formed in the remote plasma region 2015. The remote plasma region 2015 houses the remote plasma.

The plurality of holes in the ion suppressor 2023 may be configured to control the passage of the activated gas, i.e., the ionic, radical, and/or neutral species, through the ion suppressor 2023. For example, the aspect ratio of the holes, or the hole diameter to length, and/or the geometry of the holes may be selected so that the flow of ionically-charged species in the activated gas passing through the ion suppressor 2023 is reduced. The holes in the ion suppressor 2023 may include a tapered portion that faces the remote plasma region 2015, and a cylindrical portion that faces the showerhead 2025. The cylindrical portion may be shaped and dimensioned to control the flow of ionic species passing to and through the showerhead 2025. An adjustable electrical bias may also be applied to the ion suppressor 2023 as an additional means to control the flow of ionic species through the suppressor. The ion suppressor 2023 may function to reduce the amount or eliminate ionically charged species traveling from the plasma generation region to the substrate. Uncharged neutral and radical species may still pass through the openings in the ion suppressor to react with the substrate.

Remote plasma power can be of a variety of frequencies or a combination of multiple frequencies. The remote plasma may be provided by remote RF power delivered from the remote plasma power supply 2068 to the top plate 2017 relative to the ion suppressor 2023, relative to the showerhead 2025, or relative to both the ion suppressor 2023 and the showerhead 2025 (as shown). The remote RF power may be between 10 watts and 10,000 watts, between 10 watts and 5,000 watts, preferably between 25 watts and 2000 watts or more preferably between 50 watts and 1500 watts to increase the longevity of chamber components. The remote RF frequency applied in the exemplary processing system to the remote plasma region may be low RF frequencies less than 200 kHz, higher RF frequencies between 10 MHz and 15 MHz, or microwave frequencies greater than 1 GHz in embodiments. The plasma power may be capacitively-coupled (CCP) or inductively-coupled (ICP) into the remote plasma region.

Plasma effluents derived from the etchant precursors in the remote plasma region 2015 may travel through apertures in the ion suppressor 2023, and/or the showerhead 2025 and into the substrate processing region 2033 through through-holes or the first fluid channels 2019 of the showerhead in embodiments. Little or no plasma may be present in substrate processing region 2033 during the remote plasma etch process. The plasma effluents react with the substrate to etch material from the substrate.

The showerhead 2025 may be a dual channel showerhead (DCSH). The dual channel showerhead 2025 may provide for etching processes that allow for separation of etchants outside of the substrate processing region 2033 to provide limited interaction with chamber components and each other prior to being delivered into the substrate processing region 2033. The showerhead 2025 may comprise an upper plate 2014 and a lower plate 2016. The plates may be coupled with one another to define a volume 2018 between the plates. The plate configuration may provide the first fluid channels 2019 through the upper and lower plates, and the second fluid channels 2021 through the lower plate 2016. The formed channels may be configured to provide fluid access from the volume 2018 through the lower plate 2016 via the second fluid channels 2021 alone, and the first fluid channels 2019 may be fluidly isolated from the volume 2018 between the plates and the second fluid channels 2021. The volume 2018 may be fluidly accessible through a side of the showerhead 2025 and used to supply an unexcited precursor in embodiments.

A bias plasma power may be present in the substrate processing region in embodiments. The bias plasma may be used alone or to further excite plasma effluents already excited in the remote plasma. The bias plasma refers to a local plasma located above the substrate and inside the substrate processing region. The term bias plasma is used since the plasma effluents may be ionized and/or accelerated towards the substrate to beneficially accelerate or provide incoming alignment to some etch processes. In embodiments, a bias plasma may be present when no remote plasma is used. The bias plasma may be formed by applying bias plasma power from a bias plasma power supply 2070 to the substrate 2055/pedestal 2065 relative to the ion suppressor 2023, relative to the showerhead 2025, or relative to both the ion suppressor 2023 and the showerhead 2025 (as shown). The bias RF plasma power may be lower than the remote RF power. The bias RF plasma power may be below 20%, below 15%, below 10% or below 5% of the remote RF plasma power. The bias RF plasma power may be between 1 watt and 1,000 watts, between 1 watt and 500 watts, or between 2 watts and 100 watts in embodiments. The bias RF plasma frequency applied in the exemplary processing system to the substrate processing region may be low RF plasma frequencies less than 200 kHz, higher RF plasma frequencies between 10 MHz and 15 MHz, or microwave frequencies greater than 1 GHz in embodiments. The plasma power may be capacitively-coupled (CCP) or inductively-coupled (ICP) into the substrate plasma region.

A waste of electrical energy may be reduced, avoided or minimized, in embodiments, by including a remote plasma power matching circuit 2069 between the remote plasma power supply 2068 and the top plate 2017. A bias plasma power matching circuit 2071 may be electrically disposed between the bias plasma power supply 2070 and the substrate 2055 and/or pedestal 2065, according to embodiments, to reduce, avoid or minimize the power demanded by the bias plasma power supply 2070 to achieve a target power in the substrate processing region 2033.

Substrate processing chamber 2001 may be used to deposit or etch materials or perform operations discussed in relation to the present technology. Substrate processing chamber 2001 may be utilized with a plasma formed in either the remote plasma region 2015 or the substrate processing region 2033. In embodiments, a plasma may be in each of the remote plasma region 2015 and the substrate processing region 2033 contemporaneously in the etching or deposition operations described herein. Substrate processing chamber 2001 is included only as an exemplary chamber that may be utilized in conjunction with the present technology. It is to be understood that operations of the present technology may be performed in substrate processing chamber 2001 or any number of other chambers.

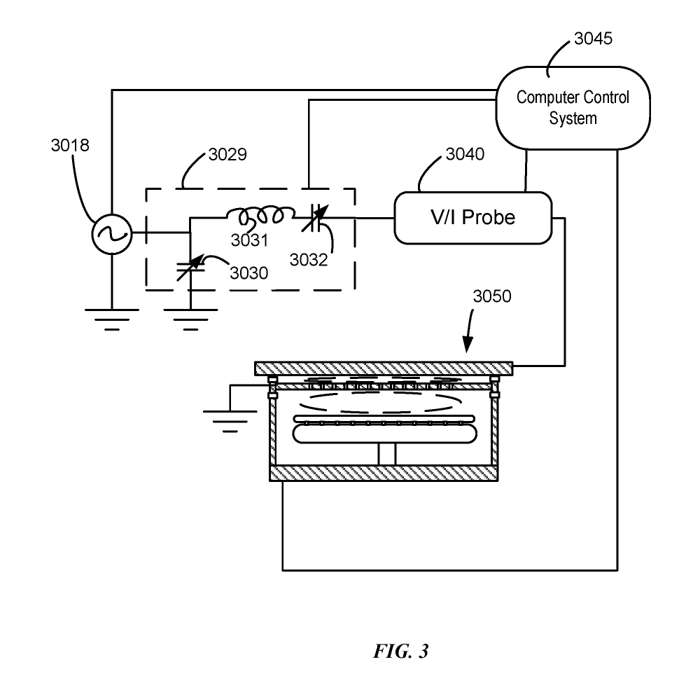

FIG. 3 shows a schematic of an exemplary remote plasma power supply matching circuit according to the present technology. The exemplary circuit applies to a remote plasma, however, the technologies described herein may be applied to a local (bias) plasma in embodiments. A remote plasma power supply 3018 delivers RF power to a matching circuit 3029. The matching circuit 3029 may include a first variable capacitor 3030, a fixed inductor 3031 and a second variable capacitor 3032. A V/I probe 3040 receives the output from the matching circuit 3029 and may be used to measure voltage spectrum properties, current spectrum properties, as well as any phase difference between the voltage spectrum and current spectrum. The voltage output from the V/I probe 3040 is delivered to the substrate by way of a pedestal in the substrate processing chamber 3050. A computer control system 3045 is configured to output instructions to all the components listed and to receive data from the components in embodiments. The matching circuit 3029 is used to adjust the impedance of the assembly outside remote plasma power supply 3018 to equal 50Ω, if possible, to “match” the internal output impedance of the remote plasma power supply 3018.

Conventionally methods have been used to predict and/or compensate for variation in physical components of plasma-based substrate processing chambers. These conventional methods do not provide reproducible substrate processing results when compared with the methods described herein. An exemplary conventional method may involve measuring the power variation resulting from each individual component which may include the RF power generator, an RF transmission cable, the RF matching circuit, the substrate processing chamber, and even variations in the plasma itself (precursor concentration and distribution). Any errors in each of these RF components add together producing excessive uncertainty in the predicted power inside the plasma region. Benefits of the processes described herein include improved accuracy and making the measurement during processing which improves equipment utilization and decreases manufacturing costs. The processes described herein may be used to maintain consistent results of a plasma process in a substrate processing chamber during and/or before processing. A benefit of using the processes described herein further includes a reduction in hardware complexity and system downtime compared to alternatives. The individual components may vary all in the same direction or in a variety of directions and the feedback mechanism described herein will tolerate these variations.

Another conventional method for predicting the plasma power delivered into the chamber involves the use of a network analyzer. However, the plasma power must be off during such a measurement which reduces accuracy and requires offline rather than online measurement. Other techniques may produce inaccurate results for phase angles of greater than 75° between the voltage and current spectra. Another conventional technique for determining plasma power into the plasma region involves the use of a directional coupler to siphon off a small portion of the plasma energy and then deducing the power delivered. A directional coupler may be used online (during processing), however, the uncertainty may be greater than 20% as a result of the small sampled power as well as a strong dependence on environmental factors. The methods described herein use alternative online measurements to determine whether plasma power should be adjusted and match substrate processing results (e.g. etch rate) across different hardware.

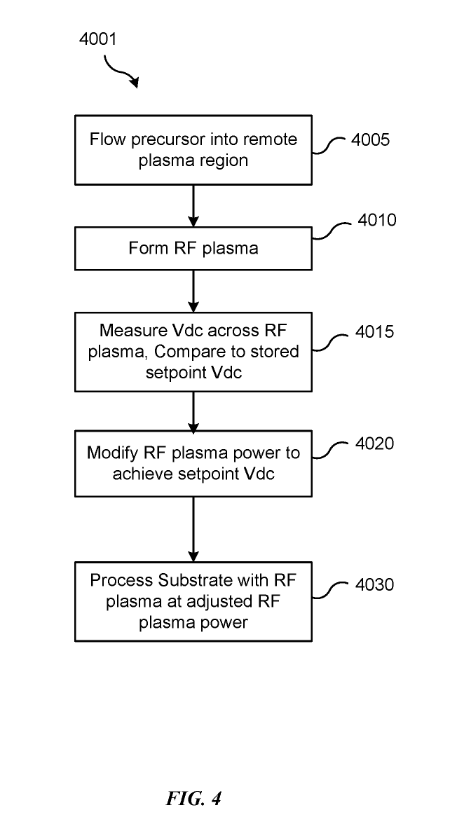

FIG. 4 shows selected operations in a method 4001 of processing a patterned substrate (e.g. etching using a remote and/or local plasma to excite etchants) in the substrate processing chamber 2001 as previously described. The method 4001 may include one or more operations prior to the initiation of the method, including front-end processing, deposition, etching, polishing, cleaning, or any other operations that may be performed prior to the described operations. A processed substrate, which may be a semiconductor wafer of any size, may be placed within the substrate processing chamber for the method 4001. Subsequent operations to those discussed with respect to method 4001 may also be performed in the same chamber or in different chambers as would be readily appreciated by the skilled artisan.

The method 4001 may optionally include placing a patterned substrate into a substrate processing region of a semiconductor processing chamber. The semiconductor substrate may include a plurality of exposed portions of various distinct materials. The method 4001 includes flowing a precursor (e.g. a fluorine-containing precursor) into a remote plasma region of a semiconductor processing chamber at operation 4005. The method 4001 includes turning on the RF power in the remote plasma region and forming a remote plasma in operation 4010. The remote plasma region and the substrate processing region are both in the same substrate processing chamber but are separated by a porous barrier such as a showerhead. In general, the precursor may be a deposition precursor or an etching precursor. The etching precursor may include a halogen (e.g. fluorine or chlorine).

The voltage and current waveforms are acquired in a V/I probe prior to application to the top plate of the remote plasma region. The voltage is applied to the top plate relative to the showerhead or to the showerhead relative to the top plate. In the case of a local plasma (not shown), the voltage may be applied to the substrate pedestal relative to the showerhead or to the showerhead relative to the substrate pedestal. The DC voltage (Vdc) is measured across the remote plasma in operation 4015. The DC voltage was found to correlate linearly (as discussed with reference to subsequent figures) with measurable substrate processing results. The DC voltage is not an applied voltage but naturally arises as a result of application of the AC voltage from the RF plasma power supply. The DC voltage has been found preferable to the AC voltage despite having a lower magnitude than the AC voltage. Vdc is compared with a stored setpoint DC voltage and the RF plasma power is adjusted until Vdc reaches the setpoint. The RF plasma power is adjusted at intervals throughout the process, in embodiments, to keep Vdc at the setpoint value. The substrate is processed in operation 4030 (e.g. etched with fluorine-containing plasma effluents). Operations 4015 and 4020 may occur in sequence and may precede operation 4030 according to embodiments. Alternatively, operation 4015 and 4020 may occur in sequence and repeated during operation 4030 in embodiments. Operations 4015 and 4020 may be performed one time, two times, more than ten times, more than forty times or more than one hundred times during operation 4030 according to embodiments.

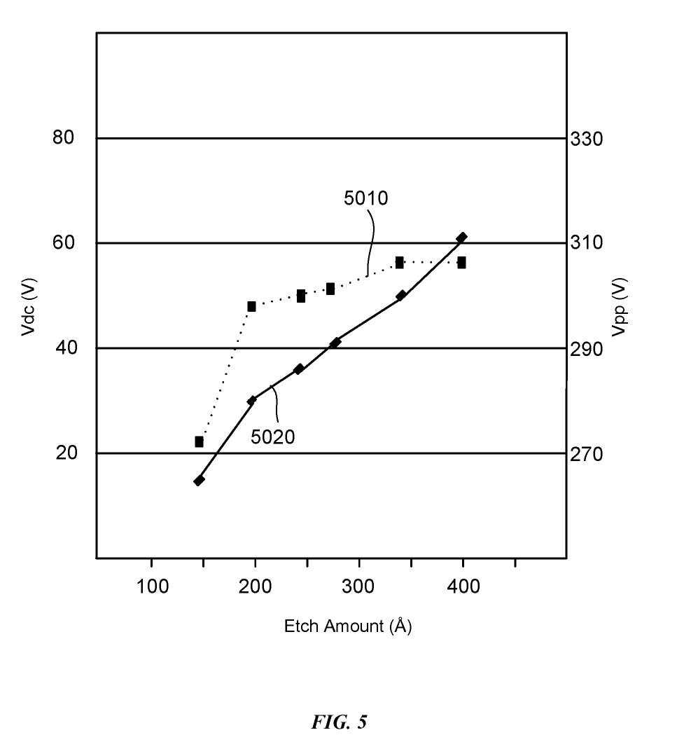

FIG. 5 is a chart showing a correlation between etch amount and DC voltage measurement 5010 across a process plasma according to embodiments of the present technology. The etch amount is proportional to etch rate since the same etch duration was used for all measurements. Also shown is the corresponding AC voltage measurement 5020 across the process plasma. The DC voltage measurement 5010 values are shown on the left-hand vertical axis, whereas the AC voltage measurement 5020 values are shown on the right-hand vertical axis. The DC voltage values are relatively linear in response to the etch rate. On the other hand, the AC voltage values correlate poorly with the etch rate. Feeding back the AC voltage would not provide a reproducible etch rate of during substrate processing with a nonlinear response. Furthermore, the AC voltage was found to cluster in a series of discrete values, further confusing a feedback loop. The DC voltages were found to vary smoothly and not cluster in embodiments.

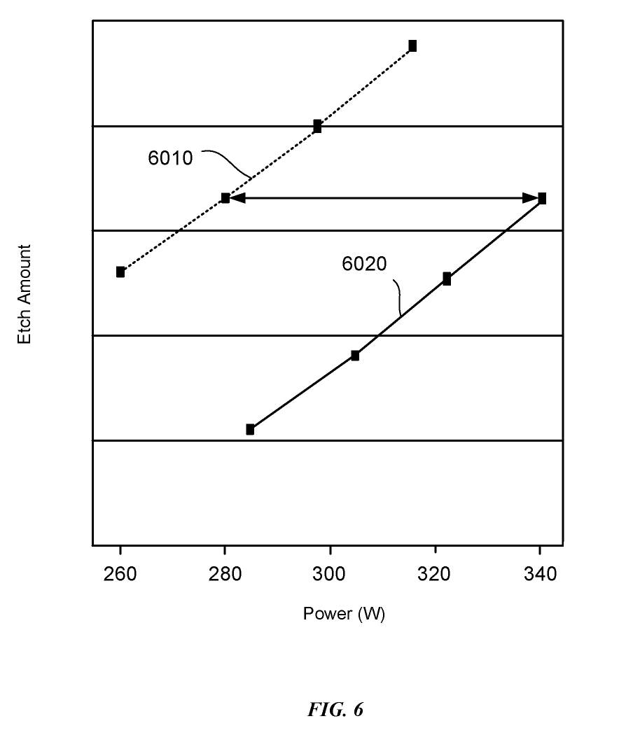

FIG. 6 is a chart showing a correlation between etch rate and the plasma power supplied at the power supply for a first substrate processing chamber 6010 and a second substrate processing chamber 6020 according to embodiments of the present technology. The two substrate processing chambers were intentionally made dissimilar by adding a spacer to reduce the efficiency with which plasma is passed into the remote plasma region. As before, the plasma region may be a bias plasma in a substrate processing region according to embodiments. The plasma power supplied to the second substrate processing chamber 6020 had to be about 60 W higher than the plasma power supplied to the first substrate processing chamber 6010 to achieve the same etch rate. The second substrate processing chamber was detuned by installation of the spacer.

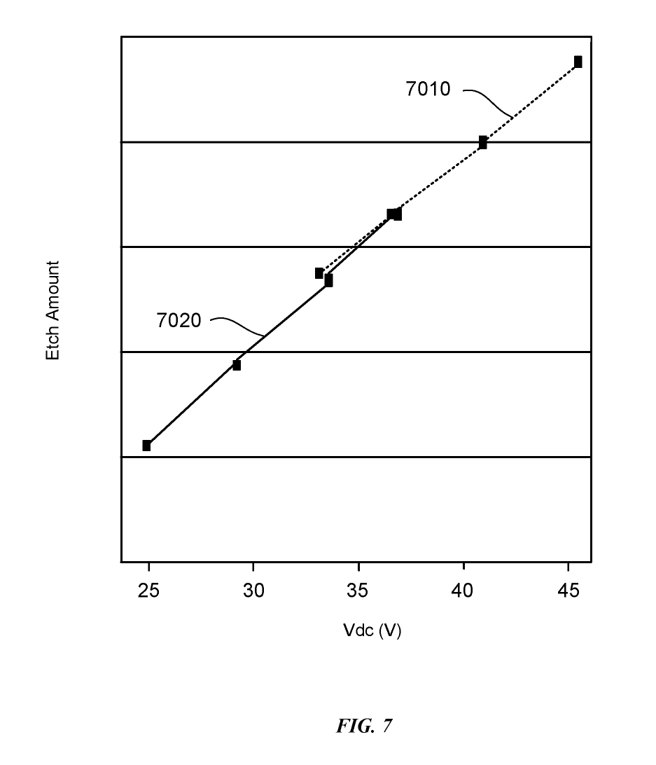

FIG. 7 is a chart showing a correlation between etch rate and the DC voltage measured across the plasma for a first substrate processing chamber 7010 and a detuned second substrate processing chamber 7020 according to embodiments of the present technology. The two correlations are not only linear but collinear which means that when the plasma power is adjusted to make the DC voltage attain a setpoint value (e.g. 35 volts), then the etch rate may be selected. The physical dissimilarity intentionally introduced between the first substrate processing chamber and the detuned second substrate processing chamber was made much larger than the mis-match expected originating from normal manufacturing variations. A single measurement may be made of Vdc and the plasma power may be adjusted to achieve a desired level of power transmitted into the plasma region during a hypothetical feedback loop attempting to achieve the setpoint value. Multiple measurements and adjustments may be made to maintain the setpoint value during some or all of the substrate processing. In embodiments, a measurement is made and the RF plasma power is adjusted at least every 0.1 seconds, at least every 0.2 seconds, at least every 0.3 seconds, at least every 0.5 seconds, or at least every 1 second.

The pressure in the remote plasma region and/or in the substrate processing region may be selected to benefit the deposition or etching process (operation 4030 in the previous example). The pressure within the remote plasma region may be below 50 Torr, below 40 Torr, below 20 Torr, below 10 Torr, below 5 Torr, below 2 Torr, below 1 Torr, below 800 mTorr, below 600 mTorr, or below 500 mTorr according to embodiments. The pressure in the remote plasma region may be maintained above 70 mTorr, above 100 mTorr, above 200 mTorr, above 500 mTorr, above 1 Torr, above 2 Torr, or above 5 Torr in embodiments. For local (bias) plasmas, the pressure within the substrate processing region may be below 50 Torr, below 40 Torr, below 20 Torr, below 10 Torr, below 5 Torr, below 2 Torr, below 1 Torr, below 800 mTorr, below 600 mTorr, or below 500 mTorr according to embodiments. The pressure in the substrate processing region may be maintained above 70 mTorr, above 100 mTorr, above 200 mTorr, above 500 mTorr, above 1 Torr, above 2 Torr, or above 5 Torr in embodiments. Inert additives or diluents (e.g. nitrogen (N₂) or argon (Ar)) may be combined with a deposition or etching precursor according to embodiments. A benefit of the processes described herein includes determining the health of low pressure plasmas which may be more temperamental.

The RF plasma power applied to either the remote plasma region or the substrate processing region may be between 1 watt and 1,000 watts, between 1 watt and 500 watts, or between 2 watts and 100 watts in embodiments. The RF plasma frequency applied to the remote plasma region or the substrate processing region may be low RF plasma frequencies less than 200 kHz, higher RF plasma frequencies between 10 MHz and 15 MHz, or microwave frequencies greater than 1 GHz according to embodiments. The RF plasma power may be capacitively-coupled (CCP) or inductively-coupled (ICP) into either or both the remote plasma region and/or the substrate processing region. The DC voltage measured herein may be between 10 volts and 80 volts, between 15 volts and 70 volts or between 20 volts and 60 volts according to embodiments.

Substrate processing may be performed while the patterned substrate is between 25° C. and 600° C. In embodiments, the substrate temperature may be greater than 25° C., greater than 50° C., greater than 100° C., greater than 150° C., or greater than 200° C. during substrate processing. The substrate temperature may be less than 600° C., less than 550° C., less than 500° C., less than 450° C., less than 400° C., or less than 350° C. during substrate processing according to embodiments.

All film properties and process parameters given for each example provided herein apply to all other examples as well. The deposition or etching precursor may be flowed into the remote plasma region or the substrate processing region, as appropriate, at a flow rate between 10 sccm and 4000 sccm, between 200 sccm and 3000 sccm, or between 500 sccm and 2000 sccm in embodiments.

When a remote plasma is used but a bias plasm is not, the substrate processing region may be described herein as “plasma-free” during the processes described herein. Any or all of the methods described herein may have a low electron temperature in the substrate processing region during the processes to ensure the beneficial chemical reactions deep within the porous film according to embodiments. The electron temperature may be measured using a Langmuir probe in the substrate processing region. In embodiments, the electron temperature may be less than 0.5 eV, less than 0.45 eV, less than 0.4 eV, or less than 0.35 eV according to embodiments. “Plasma-free” may or may not, in embodiments, necessarily mean the region is devoid of plasma. Ionized species and free electrons created within the plasma region may travel through pores (apertures) in the partition (showerhead) at exceedingly small concentrations. The borders of the plasma in the chamber plasma region are hard to define and may encroach upon the substrate processing region through the apertures in the showerhead. Furthermore, a low intensity plasma may be created in the substrate processing region without eliminating desirable features of the processes described herein. All causes for a plasma having much lower intensity ion density than the chamber plasma region during the creation of the excited plasma effluents may or may not deviate from the scope of “plasma-free” according to embodiments.

In the preceding description, for the purposes of explanation, numerous details have been set forth in order to provide an understanding of various embodiments of the present technology. It will be apparent to one skilled in the art, however, that certain embodiments may be practiced without some of these details, or with additional details.

Having disclosed several embodiments, it will be recognized by those of skill in the art that various modifications, alternative constructions, and equivalents may be used without departing from the spirit of the embodiments. Additionally, a number of well-known processes and elements have not been described in order to avoid unnecessarily obscuring the present technology. Accordingly, the above description should not be taken as limiting the scope of the technology.

Where a range of values is provided, it is understood that each intervening value, to the smallest fraction of the unit of the lower limit, unless the context clearly dictates otherwise, between the upper and lower limits of that range is also specifically disclosed. Any narrower range between any stated values or unstated intervening values in a stated range and any other stated or intervening value in that stated range is encompassed. The upper and lower limits of those smaller ranges may independently be included or excluded in the range, and each range where either, neither, or both limits are included in the smaller ranges is also encompassed within the technology, subject to any specifically excluded limit in the stated range. Where the stated range includes one or both of the limits, ranges excluding either or both of those included limits are also included.

As used herein and in the appended claims, the singular forms “a”, “an”, and “the” include plural references unless the context clearly dictates otherwise. Thus, for example, reference to “a layer” includes a plurality of such layers, and reference to “the precursor” includes reference to one or more precursors and equivalents thereof known to those skilled in the art, and so forth.

Also, the words “comprise(s)”, “comprising”, “contain(s)”, “containing”, “include(s)”, and “including”, when used in this specification and in the following claims, are intended to specify the presence of stated features, integers, components, or operations, but they do not preclude the presence or addition of one or more other features, integers, components, operations, acts, or groups.

1. A method of forming a plasma, the method comprising:
flowing a precursor into a plasma region, wherein the plasma region is within a substrate processing chamber;
turning on an RF power to a first RF power level from an RF power supply disposed outside the substrate processing chamber;
forming a plasma by applying the RF power from the RF power supply in the form of an AC voltage across the plasma region;
measuring a resulting DC voltage across the plasma region, wherein the resulting DC voltage is not an applied voltage but results from application of the AC voltage across the plasma region;
calculating a second RF power level from the resulting DC voltage and a setpoint DC voltage; and
changing the RF power from the first RF power level to the second RF power level.

2. The method of forming the plasma of claim 1 wherein the resulting DC voltage is between 10 volts and 80 volts.

3. The method of forming the plasma of claim 1 wherein measuring the resulting DC voltage comprises measuring the resulting DC voltage closer to the plasma region than the RF power supply, a matching circuit and a V/I probe so the measurement is predominantly indicative of properties of the plasma.

4. The method of forming the plasma of claim 1 wherein the plasma region is a remote plasma region separated from a substrate processing region housing a semiconductor substrate and the remote plasma region is separated from the substrate processing region by a showerhead.

5. The method of forming the plasma of claim 4 wherein the substrate processing region is plasma-free during excitation of the plasma in the remote plasma region.

6. The method of forming the plasma of claim 4 wherein an electron temperature within the substrate processing region is less than 0.5 eV during excitation of the plasma.

7. The method of forming the plasma of claim 1 wherein the precursor comprises fluorine.

8. The method of forming the plasma of claim 1 wherein the RF power is between 1 watt and 1,000 watts throughout the plasma.

9. The method of forming the plasma of claim 1 wherein a pressure in the plasma region is between 70 mTorr and 50 Torr.

10. The method of forming the plasma of claim 1 wherein the plasma region is a substrate processing region housing a substrate.

11. The method of forming the plasma of claim 1 wherein an RF frequency of the RF power is less than 200 kHz, between 10 MHz and 15 MHz or greater than 1 GHz during excitation of the plasma.

12. A method of forming a remote plasma, the method comprising:
flowing a precursor into a remote plasma region, wherein the remote plasma region is separated from a substrate processing region by a showerhead and a semiconductor substrate is housed within the substrate processing region; wherein each of the remote plasma region and the substrate processing region is within a substrate processing chamber;
forming a remote plasma by applying an RF power from an RF power supply in the form of an AC voltage across the remote plasma region;
(1) measuring a DC voltage across the remote plasma region, wherein the DC voltage is not an applied voltage but results from application of the AC voltage across the remote plasma region;
(2) changing the RF power based on the DC voltage measured; and
repeating (1) and (2) during application of the RF power.

13. The method of forming the remote plasma of claim 12 wherein measuring the DC voltage comprises measuring the DC voltage closer to the remote plasma region than the RF power supply, a matching circuit and a V/I probe so the measurement is predominantly indicative of properties of the remote plasma.

14. A method of forming a plasma, the method comprising:
flowing a precursor into a remote plasma region, wherein the remote plasma region is separated from a substrate processing region housing a semiconductor substrate by a showerhead, wherein each of the remote plasma region and the substrate processing region are within a substrate processing chamber;
forming a remote plasma by applying an RF power from an RF power supply in the form of an AC voltage across the remote plasma region; and
measuring a DC voltage across the remote plasma region, wherein the DC voltage is not an applied voltage but results from application of the AC voltage across the remote plasma region and adjusting the RF power from the RF power supply a plurality of times during forming the remote plasma, wherein an amount of adjustment of the RF power depends on the DC voltage measured.

15. The method of forming the plasma of claim 14 wherein the RF power from the RF power supply is adjusted at least one hundred times while forming the remote plasma.

16. The method of forming the plasma of claim 14 wherein the remote plasma is capacitively-coupled.
